(19) United States
(12) Patent Application Publication
(10) Pub. No.: US 2025/0087562 A1
(43) Pub. Date: Mar. 13, 2025

(54) CHIP ON FILM PACKAGE AND DISPLAY DEVICE INCLUDING THE SAME

(71) Applicant: SAMSUNG ELECTRONICS CO., LTD., Suwon-si (KR)

(72) Inventors: Narae Shin, Suwon-si, Gyeonggi-do (KR); Jeongkyu Ha, Suwon-si (KR); Woonbae Kim, Suwon-si (KR); Yechung Chung, Suwon-si (KR)

(21) Appl. No.: 18/816,740

(22) Filed: Aug. 27, 2024

(30) Foreign Application Priority Data
Sep. 7, 2023 (KR) 10-2023-0119275

(51) Int. Cl. H01L 23/495; H01L 23/00; H01L 23/31

(52) U.S. Cl. CPC H01L 23/49572; H01L 23/49558; H01L 24/16; H01L 23/3157; H01L 2224/16245

(57) ABSTRACT

A chip on film package includes a base film having a first surface and a second surface which are opposite to each other, at least one first conductive line disposed on the first surface and extending in a first direction, at least one second conductive line disposed on the second surface and extending in the first direction, a semiconductor chip disposed on the first surface and connected to the at least one first conductive line through a bump structure, a protective layer covering a part of the first surface and a part of the second surface, and a display panel disposed on the first surface and connected to the at least one first conductive line, wherein the at least one second conductive line is not disposed on the second surface between the semiconductor chip and the display panel.

### CROSS-REFERENCE TO RELATED APPLICATION

This application claims priority under 35 U.S.C. § 119 to Korean Patent Application No. 10-2023-0119275, filed in the Korean Intellectual Property Office on Sep. 7, 2023, the disclosure of which is incorporated by reference herein in its entirety.

### BACKGROUND

In chip on film (COF) packages, a semiconductor chip may be mounted on a base film, and electrically connected to an external device through a conductive line in the base film. As display devices require miniaturization of bezels and thinning of panels, there is a greater need to reduce the area of contact between a COF package and a display panel.

### SUMMARY

In general, in some aspects, the present disclosure is directed toward a chip on film (COF) package having a reduced repulsive force in a bending area between a semiconductor chip and a display panel.

According to some aspects of the present disclosure, a chip on film (COF) package includes a base film having a first surface and a second surface, which are opposite to each other, at least one first conductive line disposed on the first surface of the base film and extending in a first direction, at least one second conductive line disposed on the second surface of the base film and extending in the first direction, a semiconductor chip disposed on the first surface of the base film and connected to the at least one first conductive line through a bump structure, a protective layer covering a part of the first surface and a part of the second surface, and a display panel disposed on the first surface and connected to the at least one first conductive line, wherein the at least one second conductive line is not disposed on the second surface between the semiconductor chip and the display panel.

According to some aspects of the present disclosure, a chip on film (COF) package includes a base film having an upper surface and a lower surface, a plurality of first conductive lines disposed on the upper surface of the base film and extending in a first direction and a first protective layer covering the plurality of first conductive lines, a plurality of second conductive lines disposed on the lower surface of the base film and extending in the first direction and a second protective layer covering the plurality of second conductive lines, a semiconductor chip disposed at a center of the upper surface of the base film and electrically connected to the plurality of first conductive lines, and a display panel disposed on one end of the upper surface of the base film and electrically connected to the plurality of first conductive lines, wherein the plurality of second conductive lines and the second protective layer are not disposed on an area of the lower surface of the base film from the center to the one end.

According to some aspects of the present disclosure, a display device includes a chip on film (COF) package having a base film having a first surface and a second surface opposite to the first surface, a display panel disposed to face one end of the first surface of the base film, having a front surface including a plurality of pixels and a rear surface opposite to the front surface, and having a driver printed circuit board disposed to face another end of the first surface of the base film, wherein the COF package includes at least one first conductive line disposed on the first surface of the base film and extending in a first direction, at least one second conductive line disposed on the second surface of the base film and extending in the first direction, a semiconductor chip disposed on the first surface of the base film and connected to the at least one first conductive line through a bump structure, and a protective layer covering a part of the first surface and a part of the second surface, in the COF package, the at least one second conductive line is not disposed in a bending area in which the base film is bent toward a rear surface of the display panel.

### BRIEF DESCRIPTION OF THE DRAWINGS

Exemplary implementations will be more clearly understood from the following detailed description, taken in conjunction with the accompanying drawings.

FIG. 1 is a perspective view showing an example of a display device according to some implementations.

FIG. 2 is a perspective view showing an example of a chip on film (COF) package according to some implementations.

FIG. 3 is a cross-sectional view showing an examples of a circuit area of the COF package of FIG. 2 according to some implementations.

FIGS. 4A, 5A, 6A, 7A, 8A, 9A, 10A, and 11A are cross-sectional views showing examples of display devices according to some implementations.

FIGS. 4B, 5B, 6B, 7B, 8B, 9B, 10B, and 11B are plan views showing examples of upper surfaces of COF packages included in FIGS. 4A, 5A, 6A, 7A, 8A, 9A, 10A, and 11A respectively corresponding thereto according to some implementations.

FIGS. 4C, 5C, 6C, 7C, 8C, 9C, 10C, and 11C are plan views showing examples of lower surfaces of the COF packages included in FIGS. 4A, 5A, 6A, 7A, 8A, 9A, 10A, and 11A respectively corresponding thereto according to some implementations.

### DETAILED DESCRIPTION

Hereinafter, exemplary implementation will be described in detail with reference to the accompanying drawings.

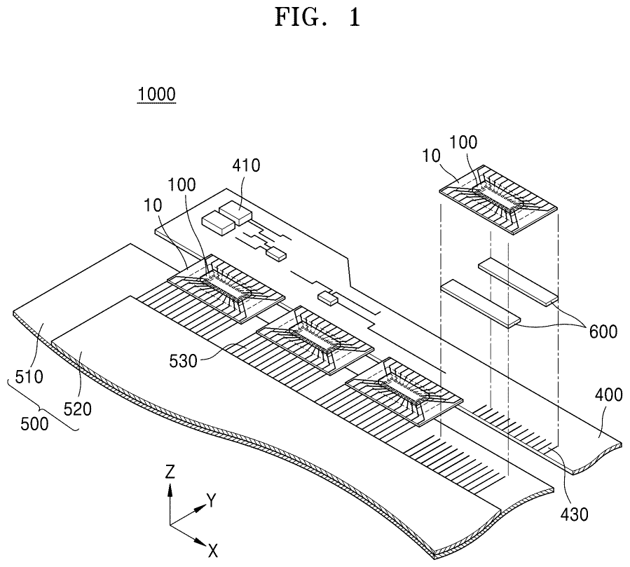

FIG. 1 is a perspective view showing an examples of a display device 1000 according to some implementations. In FIG. 1, the display device 1000 includes at least one chip on film (COF) package 10, a driver printed circuit board 400, and a display panel 500.

The COF package 10 may include a semiconductor chip 100, which is a display driver IC (DDI). In some implementations, one semiconductor chip 100 may be disposed in one COF package 10. In some implementations, different types of semiconductor chips 100 may be disposed in one COF package 10. For example, the semiconductor chip 100 may include a source driver chip and/or a gate driver chip.

The COF package 10 may be located between the driver printed circuit board 400 and the display panel 500 and bonded and connected to each of the driver printed circuit board 400 and the display panel 500. For example, the COF package 10 may receive a signal output from the driver printed circuit board 400 and transmit the signal to the display panel 500.

One or more driver circuit chips 410 capable of simultaneously or sequentially applying power and signals to the COF package 10 may be mounted on the driver printed circuit board 400.

The display panel 500 may include, for example, a liquid crystal display (LCD) panel, a light emitting diode (LED) panel, an organic LED (OLED) panel, a plasma display panel (PDP), etc.

The COF package 10 may be electrically connected to each of a driver connection wiring 430 of the driver printed circuit board 400 and a panel connection wiring 530 of the display panel 500. In some implementations, one COF package 10 may be connected between the driver printed circuit board 400 and the display panel 500. For example, when the display panel 500 provides a screen of small area, such as a mobile phone, or supports a relatively low resolution, the display device 1000 may include one COF package 10.

In some implementations, a plurality of COF packages 10 may be connected to each other between the driver printed circuit board 400 and the display panel 500. For example, when the display panel 500 provides a screen of large area, such as a television, or supports a relatively high resolution, the display device 1000 may include the plurality of COF packages 10.

The COF package 10 may be connected to only one side of the display panel 500. However, the inventive concept is not limited to this, and in some implementations, one or more COF packages 10 may be connected to each of two or more sides of the display panel 500.

The display panel 500 may include a transparent substrate 510, an image area 520 formed on the transparent substrate 510, and the panel connection wiring 530. The transparent substrate 510 may be, for example, a glass substrate or a flexible substrate. A plurality of pixels of the image area 520 may be connected to a plurality of panel connection wirings 530 respectively corresponding thereto and operate according to signals provided by the semiconductor chip 100 mounted on the COF package 10.

An input pad may be formed on one end of the COF package 10, and an output pad may be formed on the other end thereof. The input pad and the output pad may be respectively connected to the driver connection wiring 430 of the driver printed circuit board 400 and the panel connection wiring 530 of the display panel 500 by an anisotropic conductive layer 600.

The anisotropic conductive layer 600 may be, for example, an anisotropic conductive film or an anisotropic conductive paste. The anisotropic conductive layer 600 may have a structure in which conductive particles are dispersed within an insulating adhesive layer. In addition, the anisotropic conductive layer 600 may be electrically conducted only in a vertical direction (Z direction), which is an electrode direction, when connected, and may have an anisotropic electrical property that is insulated in a first direction (X direction), which is a direction between adjacent electrodes. When an adhesive is melted by applying heat and pressure to the anisotropic conductive layer 600, while conductive particles are disposed between opposing electrodes, for example, between the input pad and the drive connection wiring 430 and between the output pad and the panel connection wiring 530 and conducted, adjacent electrodes may be filled with the adhesive and insulated.

Hereinafter, the COF package 10 included in the display device 1000 according to some implementations is described in detail.

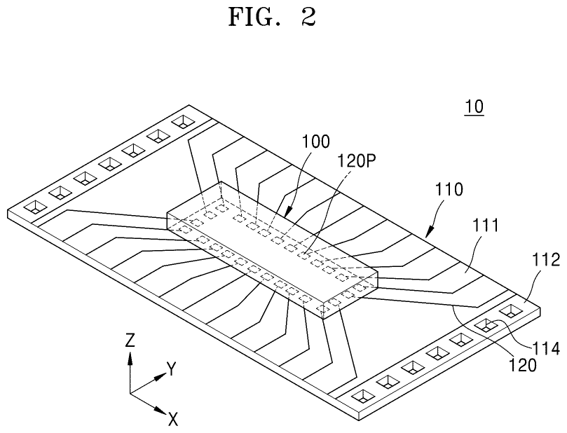

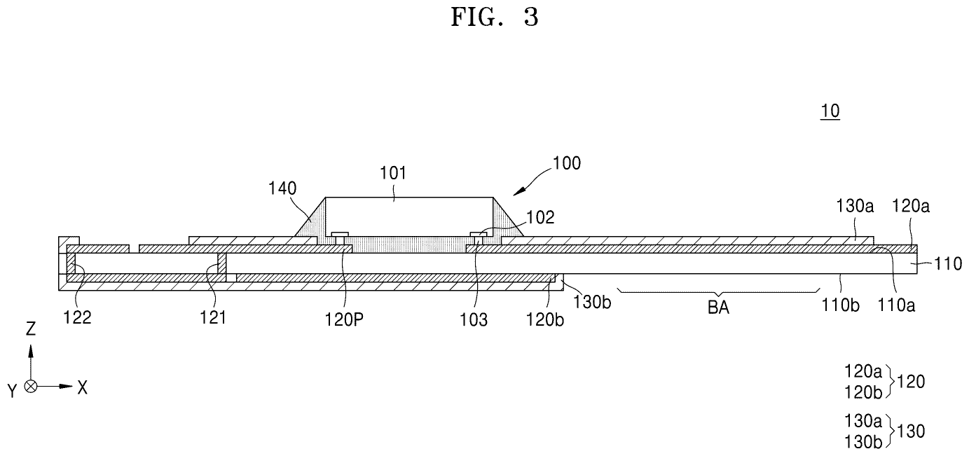

FIG. 2 is a perspective view showing an example of a COF package 10 according to some implementations, and FIG. 3 is a cross-sectional view showing an example of circuit area 111 of the COF package 10 of FIG. 2 according to some implementations. In FIGS. 2 and 3, the COF package 10 includes the semiconductor chip 100, a base film 110, and conductive lines 120. The semiconductor chip 100 may be a DDI chip used to drive the display device 1000 (see FIG. 1).

In some implementations, the semiconductor chip 100 may be a source driver chip that generates an image signal by using a data signal transmitted from a timing controller and outputs the image signal to the display panel 500 (see FIG. 1). Alternatively, the semiconductor chip 100 may be a gate driver chip that outputs a scan signal including an on/off signal of a transistor to the display panel 500 (see FIG. 1).

However, the type of the semiconductor chip 100 is not limited thereto, and in some implementations, when the COF package 10 is coupled to an electronic device other than the display device 1000 (see FIG. 1), the semiconductor chip 100 may be a chip that drives the electronic device.

For convenience of explanation, one semiconductor chip 100 is shown in the drawing, but the number of semiconductor chips 100 is not limited thereto. In some implementations, due to the characteristics of the display device 1000 (see FIG. 1), the number of source driver chips may be equal to or greater than the number of gate driver chips.

In addition, the semiconductor chip 100 may have a long side 100L in the first direction (X direction) and a short side 100S in a second direction (Y direction) perpendicular to the first direction (X direction). For example, the semiconductor chip 100 may have a rectangular shape.

The semiconductor chip 100 may include a substrate 101 and a bump pad 102. The substrate 101 is a semiconductor substrate and may have an active surface and an inactive surface which are opposite to each other. Specifically, the substrate 101 may be a silicon (Si) wafer including crystalline silicon, polycrystalline silicon, or amorphous silicon. Alternatively, the substrate 101 may include a semiconductor element, such as germanium (Ge), or a compound semiconductor such as silicon carbide (SiC), gallium arsenide (GaAs), indium arsenide (InAs), and indium phosphide (InP).

In some implementations, the substrate 101 may have a silicon on insulator (SOI) structure. Meanwhile, the substrate 101 may include a conductive area, for example, a well doped with impurities or a structure doped with impurities. In addition, the substrate 101 may have various device isolation structures, such as a shallow trench isolation (STI) structure.

The semiconductor chip 100 may be disposed in the circuit area 111 of the base film 110, especially a chip mounting area (not shown), and may be mounted on the base film 110 through a flip chip bonding process. For example, a bump structure 103, such as a solder ball, may be disposed on a bump pad 102 exposed to the active surface of the semiconductor chip 100 and physically and electrically coupled to a conductive pad 120P on the base film 110, so that the semiconductor chip 100 may be mounted on the base film 110. A part of the bump pad 102 may serve as an input terminal, and the remaining part of the bump pad 102 may serve as an output terminal.

The bump structure 103 may be disposed to contact and be electrically connected to each of the bump pad 102 and the conductive pad 120P. Through the bump structure 103, the semiconductor chip 100 may receive at least one of a control signal, a power signal, or a ground signal for an operation of the semiconductor chip 100 from the outside, may receive a data signal to be stored in the semiconductor chip 100 from the outside, or may provide data stored in the semiconductor chip 100 to the outside. For example, the bump structure 103 may include a pillar structure, a ball structure, or a solder resist layer.

The base film 110 may be a flexible film including polyimide, which is a material with excellent coefficient of thermal expansion and durability. However, the material of the base film 110 is not limited thereto, and may include, for example, synthetic resin, such as epoxy resin, acrylic, polyether nitrile, polyether sulfone, polyethylene terephthalate, polyethylene naphthalate, etc.

The base film 110 may include the circuit area 111 at the center and perforation (PF) areas 112 disposed on both sides of the circuit area 111. The circuit area 111 may be an area in which the semiconductor chip 100 is mounted.

The PF areas 112 may be disposed on both sides of the base film 110 and may include a plurality of PF holes 114. Through the PF holes 114, reeling of the base film 110 with a winding reel and releasing of the base film 110 from the winding reel may be controlled.

Pitches of the PF holes 114 are constant, and the length of the base film 110 may be determined by the number of PF holes 114. Meanwhile, the width and length of the base film 110 are determined by the number and size of the semiconductor chips 100 mounted on the base film 110, the arrangement of the conductive lines 120 formed on the base film 110, etc.

The PF areas 112 may be cut before the COF package 10 is disposed in the display device 1000 (see FIG. 1). For example, in the COF package 10, only the circuit area 111 of the base film 110 may be disposed in the display device 1000 (see FIG. 1).

The base film 110 may have a first surface 110a and a second surface 110b which are opposite to each other. Here, the first surface 110a may be referred to as an upper surface, and the second surface 110b may be referred to as a lower surface. The semiconductor chip 100 may be mounted on the circuit area 111 of the first surface 110a.

The conductive lines 120 may be disposed on the first surface 110a and the second surface 110b of the base film 110. Here, at least one conductive line 120 disposed on the first surface 110a may be a first conductive line 120a, and at least one conductive line 120 disposed on the second surface 110b may be a second conductive line 120b. The conductive line 120 may include the conductive pad 120P on its end. The conductive line 120 may include a metal foil, for example, aluminum foil or copper foil. In some implementations, the conductive line 120 may be formed by patterning a metal layer formed on the base film 110 by a process such, as casting, laminating, or electro-plating.

The conductive pad 120P may be a part of the conductive line 120, or a part of the conductive line 120 plated with tin (Sb), gold (Au), nickel (Ni), lead (Pb), etc. In some implementations, the conductive pad 120P may be electrically connected to the conductive line 120 and may include a separately formed conductive material. The conductive pad 120P may face and be electrically connected to the bump pad 102 of the semiconductor chip 100.

A protective layer 130 may be formed on the first surface 110a and the second surface 110b of the base film 110 to protect the conductive line 120 from external physical and/or chemical damage. The protective layer 130 may cover the conductive line 120 while exposing the conductive pad 120P of the conductive lines 120 formed on the first surface 110a and the second surface 110b of the base film 110. For example, the protective layer 130 disposed on the first surface 110a may be a first protective layer 130a, and the protective layer 130 disposed on the second surface 110b may be a second protective layer 130b. The protective layer 130 may include, for example, solder resist or dry film resist. The protective layer 130 is not limited thereto, and may include a silicon oxide or silicon nitride-based insulating layer.

A molding material 140 may be filled between the semiconductor chip 100 and the base film 110 to protect the bump structure 103 and its surroundings from external physical and/or chemical damage. In some implementations, the molding material 140 may be formed by a capillary underfill process. The molding material 140 may include, for example, epoxy resin, but is not limited thereto.

As the size of the display panel 500 increases, the thickness of the display panel 500 is reduced, and the curvature of a bending area BA of the base film 110 is increased. Such an increase in the curvature of the bending area BA may increase a repulsive force of the base film 110.

Moreover, as the number of conductive pads 120P increases, the conductive lines 120 are formed on both the first surface 110a and the second surface 110b of the base film 110, the repulsive force of the base film 110 is further increased. Such an increase in the repulsive force of the base film 110 may reduce a bonding force between the base film 110 and the display panel 500 or cause cracks to occur.

Accordingly, the COF package 10 may include an area of the second surface 110b of the base film 110 in which the second conductive line 120b is not disposed. For example, in the base film 110, the second conductive line 120b is not disposed on the second surface 110b between the semiconductor chip 100 and the display panel 500.

The COF package 10 may implement the bending area BA by using the area in which the second conductive line 120b is not disposed on the second surface 110b between the semiconductor chip 100 and the display panel 500. For example, a repulsive force of the first surface 110a and a repulsive force of the second surface 110b of the base film 110 in the bending area BA may be different from each other according to whether the conductive line 120 exists. In some implementations, the length of the bending area BA in the first direction (X direction) may be about 1 mm to about 10 mm, but is not limited thereto.

The COF package 10 does not include the second conductive line 120b on the second surface 110b of the bending area BA, which is a part of the base film 110, thereby relieving the repulsive force of the base film 110 in a bent shape, maintaining the bonding force of the base film 110 in the display panel 500, and reducing the occurrence of cracks.

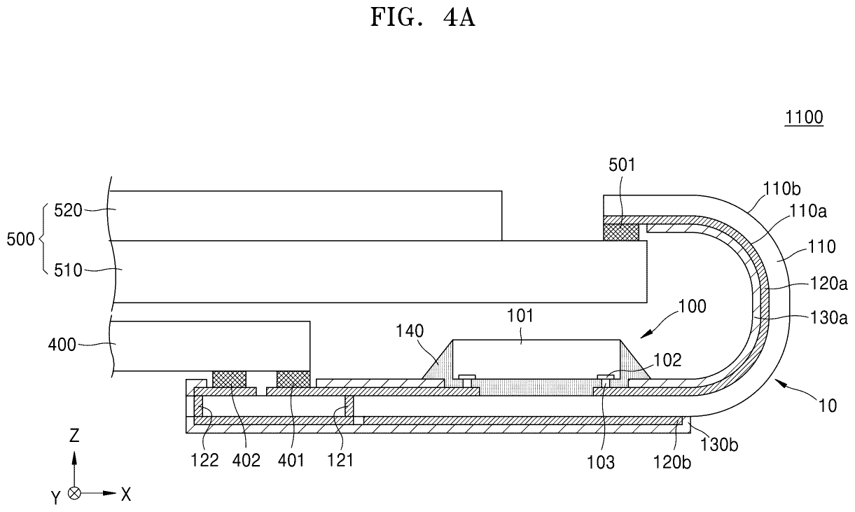

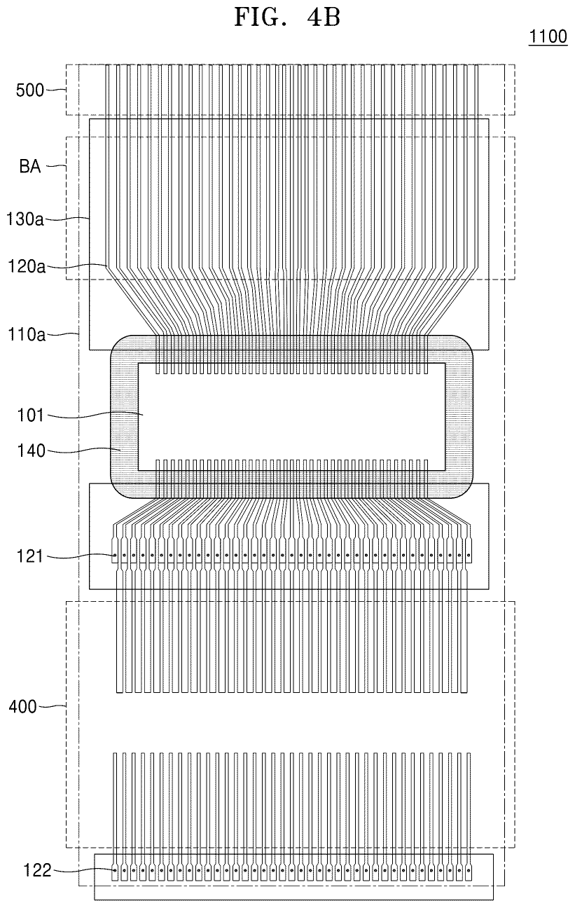

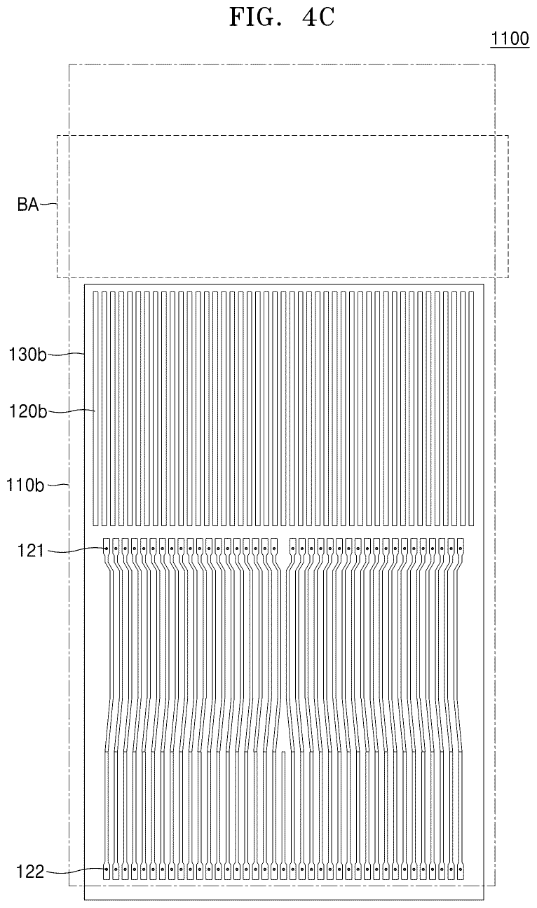

FIGS. 4A to 11C are diagrams showing examples of a display devices 1100, 1101, 1200, 1201, 1202, 1203, 1300, and 1400 and COF packages 10, 11, 20, 21, 22, 23, 30, and 40, which are respectively included in the display devices 1100, 1101, 1200, 1201, 1202, 1203, 1300, and 1400, according to some implementations.

FIGS. 4A, 5A, 6A, 7A, 8A, 9A, 10A, and 11A are cross-sectional views showing the examples of display devices 1100, 1101, 1200, 1201, 1202, 1203, 1300, and 1400, according to some implementations. FIGS. 4B, 5B, 6B, 7B, 8B, 9B, 10B, and 11B are plan views showing examples of an upper surface of the COF package 10 included in FIGS. 4A, 5A, 6A, 7A, 8A, 9A, 10A, and 11A, respectively corresponding thereto. FIGS. 4C, 5C, 6C, 7C, 8C, 9C, 10C, and 11C are plan views showing an example of a lower surface of the COF package 10 included in FIGS. 4A, 5A, 6A, 7A, 8A, 9A, 10A, and 11A, respectively corresponding thereto

In FIGS. 4A, 4B, and 4C, the display device 1100 may include the semiconductor chip 100, the driver printed circuit board 400, and the display panel 500 while the base film 110 is bent.

One end of the COF package 10 and a part of the display panel 500 may be disposed to face each other, and the other end of the COF package 10 and a part of the driver printed circuit board 400 may be disposed to face each other.

In some implementations, the COF package 10 may transmit a signal output from the driver printed circuit board 400 to the display panel 500 via the semiconductor chip 100 through the first conductive line 120a and the second conductive line 120b.

For example, one or more driver circuit chips 410 (see FIG. 1) capable of simultaneously or sequentially applying power and/or signals to the COF package 10 through the first conductive line 120a and the second conductive line 120b may be mounted on the driver printed circuit board 400.

The display panel 500 may include a transparent substrate 510 and an image area 520 including a plurality of pixels. The transparent substrate 510 may have front and rear surfaces which are opposite to each other, and the image area 520 may be disposed on the front surface of the transparent substrate 510. The COF package 10 may be bent and fixed in a direction in which the transparent substrate 510 is located, and the semiconductor chip 100 and the driver printed circuit board 400 may be disposed to face the rear surface of the transparent substrate 510.

As described above, the first conductive line 120a extending in the first direction (X direction) may be disposed on the first surface 110a of the base film 110, and the second conductive line 120b that overlaps the first conductive line 120a in the vertical direction (Z direction) may be disposed on the second surface 110b of the base film 110.

In some implementations, in the base film 110, the second conductive line 120b may be disposed only on a part of the second surface 110b. For example, the second conductive line 120b may not be formed on the bending area BA of the second surface 110b corresponding thereto from an edge portion of the semiconductor chip 100 disposed on the first surface 110a to an edge portion of the display panel 500.

In some implementations, a flat area in which both the first conductive line 120a and the second conductive line 120b are disposed, and the bending area BA in which the first conductive line 120a is disposed but the second conductive line 120b is not disposed may be present on the base film 110.

To form the display device 1100, the base film 110 may have a bent shape, and a part of the base film 110 located between the semiconductor chip 100 and the display panel 500 is bent. As described above, to prevent reduction in a bonding force between the base film 110 and the display panel 500 and the occurrence of cracks, the first conductive line 120a and the second conductive line 120b are not disposed on the bending area BA, but only the first conductive line 120a may be disposed on the first surface 110a as described above.

First to third bonding bumps 401, 402, and 501 may be disposed on the first surface 110a of the base film 110. The first to third bonding bumps 401, 402, and 501 may be connected to the first conductive line 120a. For example, among the first to third bonding bumps 401, 402, and 501, the first and second bonding bumps 401 and 402 may serve to electrically connect and bond the base film 110 to the driver printed circuit board 400. In addition, among the first to third bonding bumps 401, 402, and 501, the third bonding bump 501 may serve to electrically connect and bond the base film 110 to the display panel 500.

First and second vias 121 and 122 may be disposed in the base film 110 to electrically connect the first conductive line 120a to the second conductive line 120b. For example, the first and second vias 121 and 122 may penetrate (extend into) the base film 110 in the vertical direction (Z direction) and contact a lower surface of the first conductive line 120a and an upper surface of the second conductive line 120b.

Positions of the first and second vias 121 and 122 in the base film 110 are not limited as long as the first and second vias 121 and 122 may connect the first conductive line 120a to the second conductive line 120b. In some implementations, the first via 121 may be located in an area between the driver printed circuit board 400 and the semiconductor chip 100, and the second via 122 may be located an area below the driver printed circuit board 400.

The first protective layer 130a may be formed on at least a part of the first surface 110a of the base film 110 and cover at least a part of the first conductive line 120a, and the second protective layer 130b may be formed on at least a part of the second surface 110b and cover at least a part of the second conductive line 120b. As described above, the first protective layer 130a and the second protective layer 130b may each include solder resist, but are not limited thereto. For example, because the second conductive line 120b is not disposed on the bending area BA of the base film 110, the second protective layer 130b may also not be disposed.

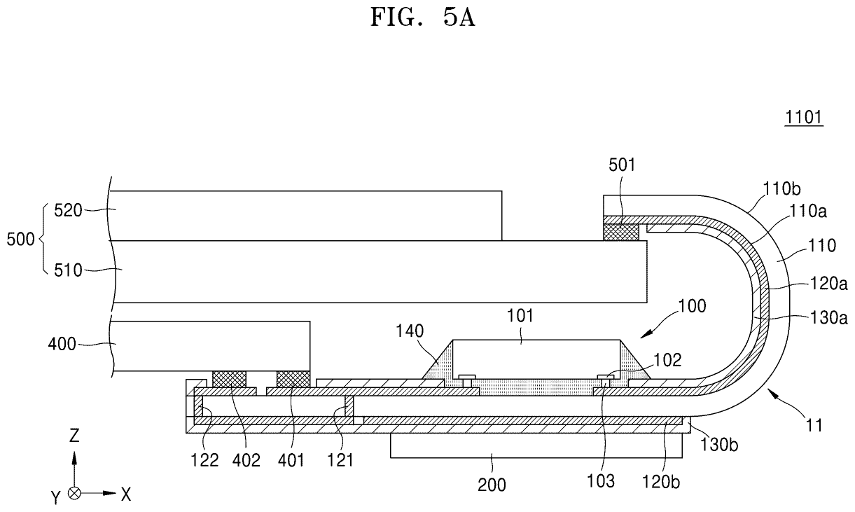

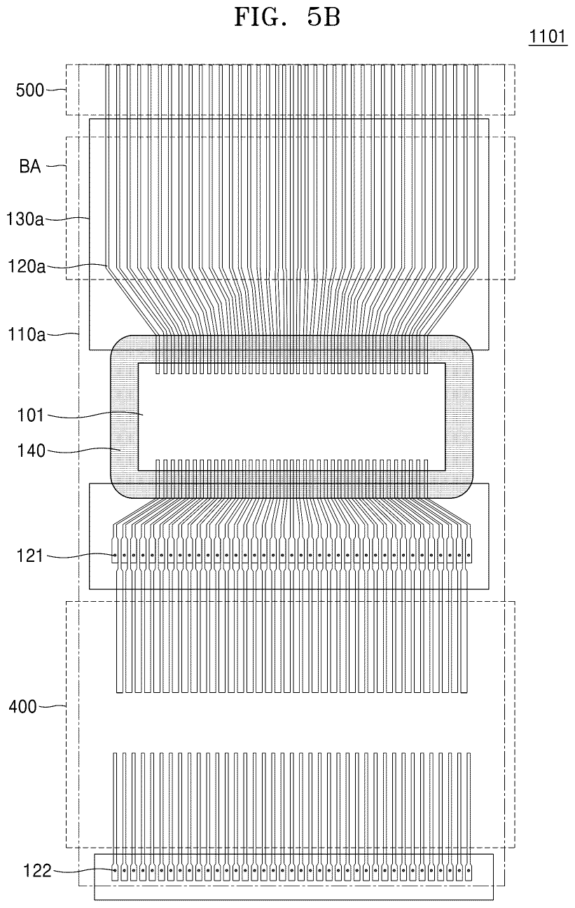

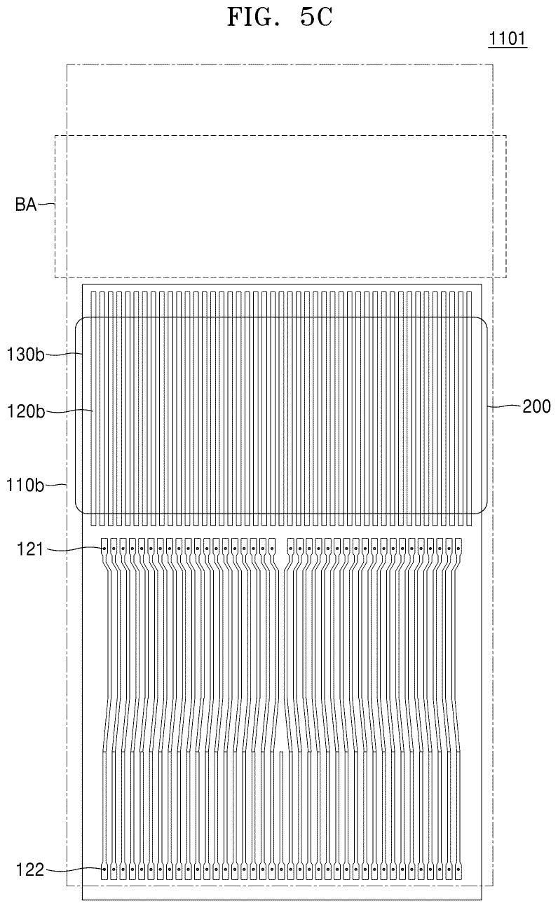

In FIGS. 5A, 5B, and 5C, the display device 1101 may include the semiconductor chip 100, the driver printed circuit board 400, and the display panel 500 while the base film 110 is bent.

Most of the components constituting the display device 1101 and materials of the components described below are substantially the same as or similar to those described with reference to FIGS. 4A, 4B, and 4C above. Accordingly, for convenience of explanation, differences from the display device 1100 described above are mainly described.

The COF package 11 included in the display device 1101 may include an attachment 200 disposed on an area in correspondence with the semiconductor chip 100 on the second surface 110b of the base film 110.

For example, the attachment 200 may include at least one of a stiffener or a heatsink. The attachment 200 as the stiffener may include a metal material and may serve to strengthen an adhesive force between the semiconductor chip 100, the molding material 140 and the base film 110 to prevent separation or peeling. In some implementations, the attachment 200 as the heatsink may serve to radiate heat generated from the semiconductor chip 100.

In order to develop efficient characteristics, the length of the attachment 200 in the first direction (X direction) may be greater than the length of a long side of the semiconductor chip 100, and the length of the attachment 200 in the second direction (Y direction) may be greater than the length of a short side of the semiconductor chip 100.

In some implementations, the attachment 200 may be in the form of a tape including metal. The metal include, for example, aluminum (Al), copper (Cu), tungsten (W), etc., but is not limited thereto.

In some implementations, the attachment 200 may include epoxy, acrylic, silicone, etc. Here, the attachment 200 may contain a thermally conductive filler to obtain an excellent heat dissipation effect. The thermally conductive filler may include alumina, boron nitride, aluminum nitride, etc.

In some implementations, the attachment 200 may include a curable material. For example, the attachment 200 may include a resin capable of thermal curing, room temperature curing, or UV curing.

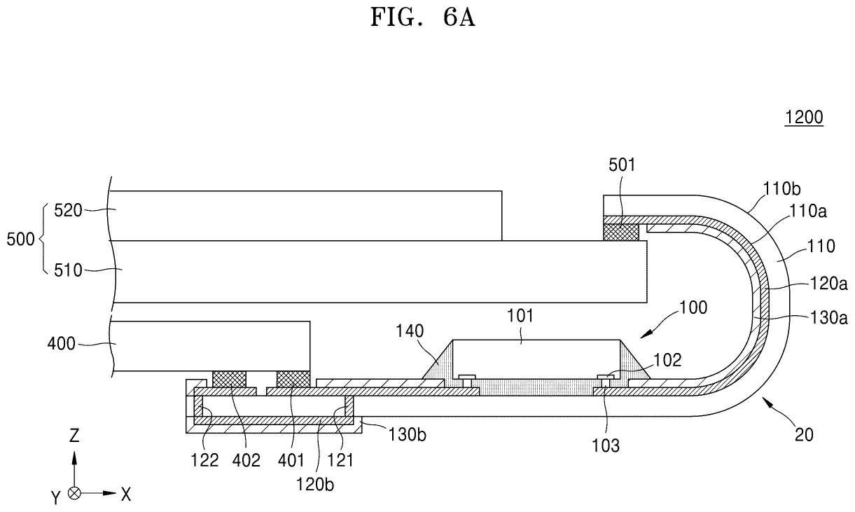

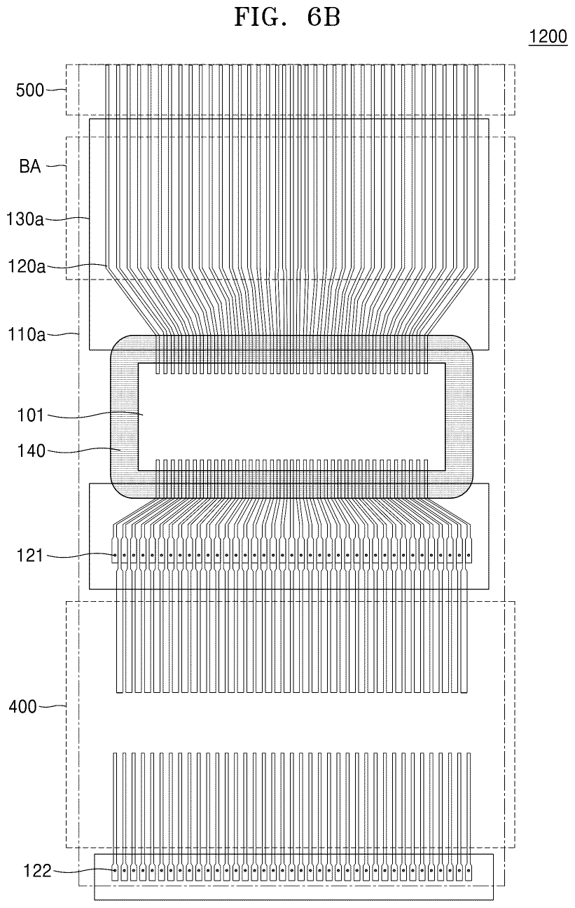

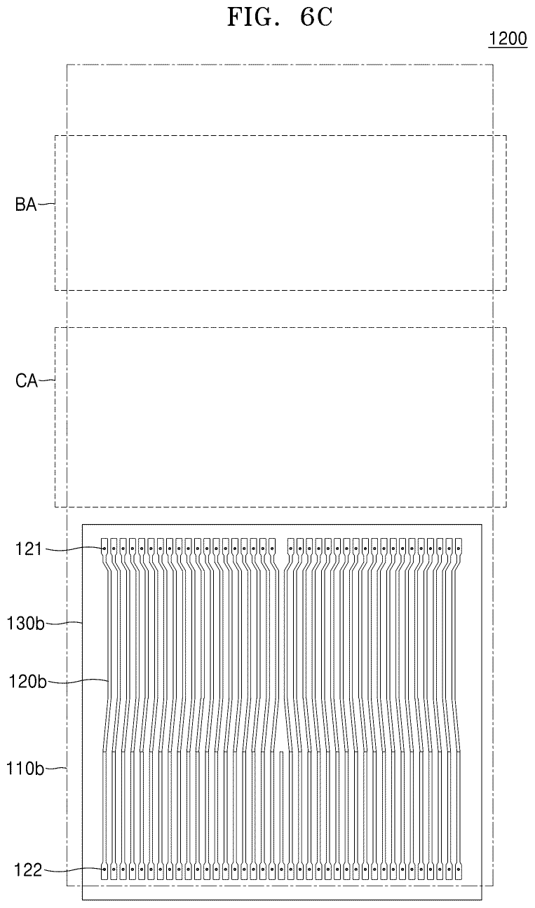

In FIGS. 6A, 6B, and 6C, the display device 1200 may include the semiconductor chip 100, the driver printed circuit board 400, and the display panel 500 while the base film 110 is bent.

Most of the components constituting the display device 1200 and materials of the components described below are substantially the same as or similar to those described with reference to FIGS. 4A, 4B, and 4C above. Therefore, for convenience of explanation, differences from the display device 1100 described above are mainly described.

In the COF package 20 included in the display device 1200, the second conductive line 120b may be disposed only on a part of the second surface 110b of the base film 110. In some implementations, the second conductive line 120b may not be formed on a chip lower area CA and the bending area BA of the second surface 110b corresponding thereto from an edge portion of the driver printed circuit board 400 disposed on the first surface 110a to an edge portion of the display panel 500. For example, in the base film 110, the second conductive line 120b may be disposed only in an area connecting the first and second vias 121 and 122.

Accordingly, the second protective layer 130b formed on at least a part of the second surface 110b and covering at least a part of the second conductive line 120b may also not be formed in the chip lower area CA and the bending area BA.

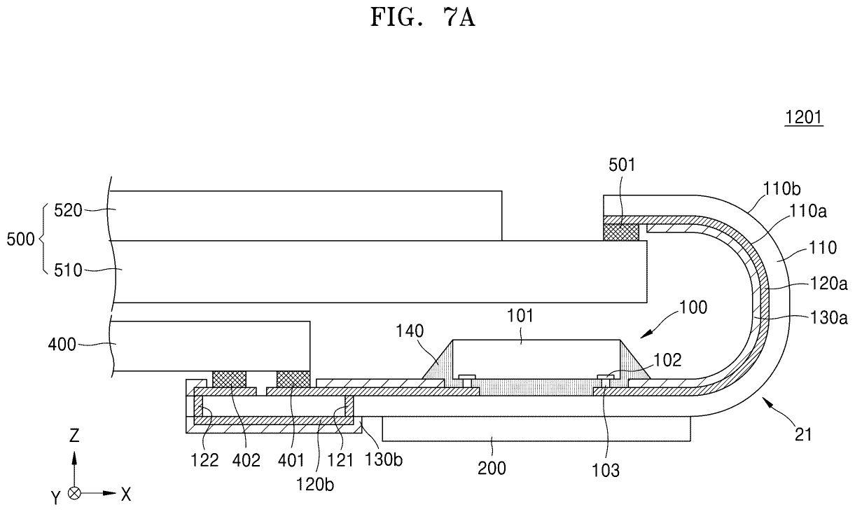

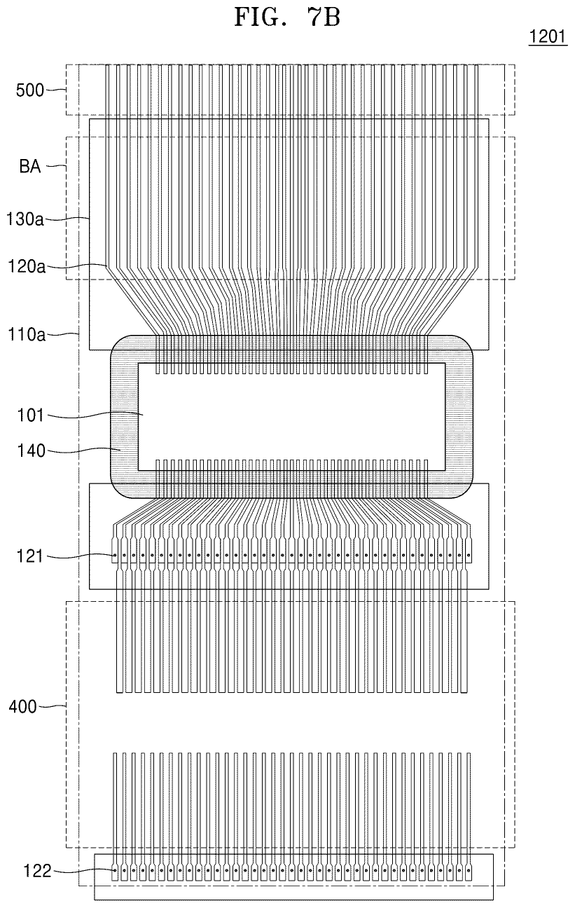

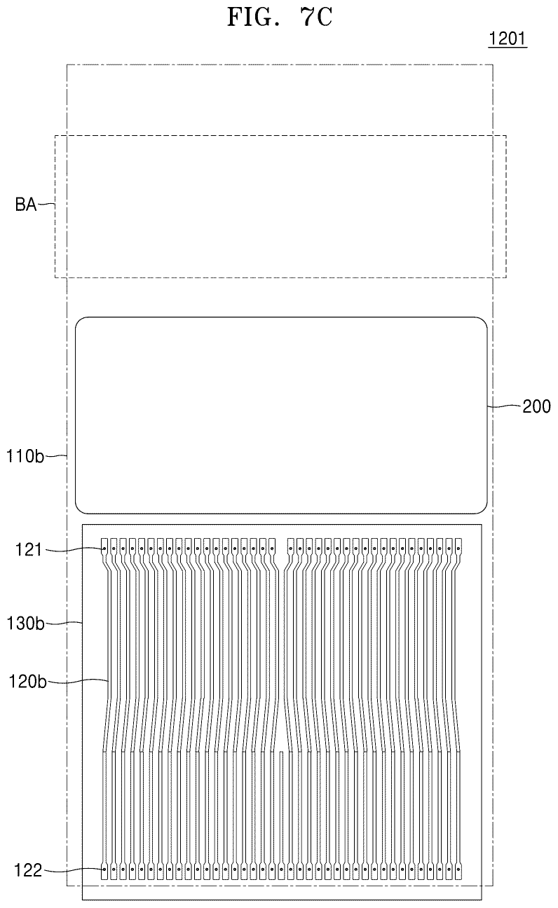

In FIGS. 7A, 7B, and 7C, the display device 1201 may include the semiconductor chip 100, the driver printed circuit board 400, and the display panel 500 while the base film 110 is bent.

Most of the components constituting the display device 1201 and materials of the components described below are substantially the same as or similar to those described with reference to FIGS. 6A, 6B, and 6C above. Accordingly, for convenience of explanation, differences from the display device 1200 described above are mainly described.

The COF package 21 included in the display device 1201 may include an attachment 200 disposed on an area in correspondence with the semiconductor chip 100 on the second surface 110b of the base film 110.

For example, the attachment 200 may include at least one of a stiffener or a heatsink. The attachment 200 as the stiffener may include a metal material and may serve to strengthen an adhesive force between the semiconductor chip 100, the molding material 140 and the base film 110 to prevent separation or peeling. In some implementations, the attachment 200 as the heatsink may serve to radiate heat generated from the semiconductor chip 100.

In addition, in the display device 1201, the attachment 200 may be directly attached to the base film 110. For example, the second conductive line 120b and the second protective layer 130b are not formed in the chip lower area CA, and the attachment 200 and the base film 110 may be bonded to directly contact with each other.

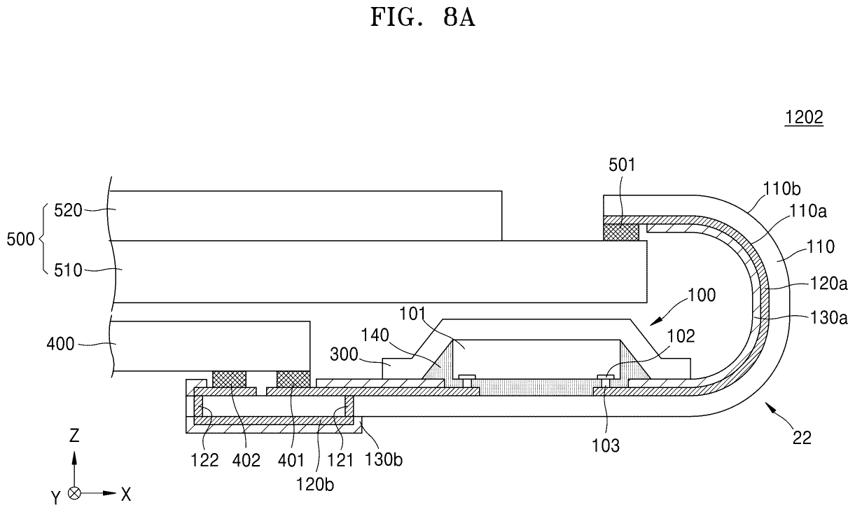

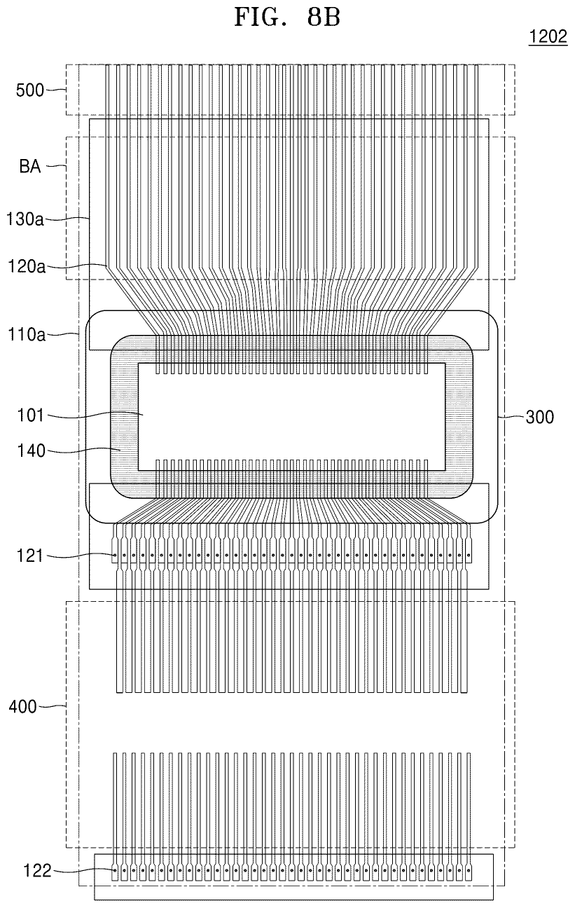

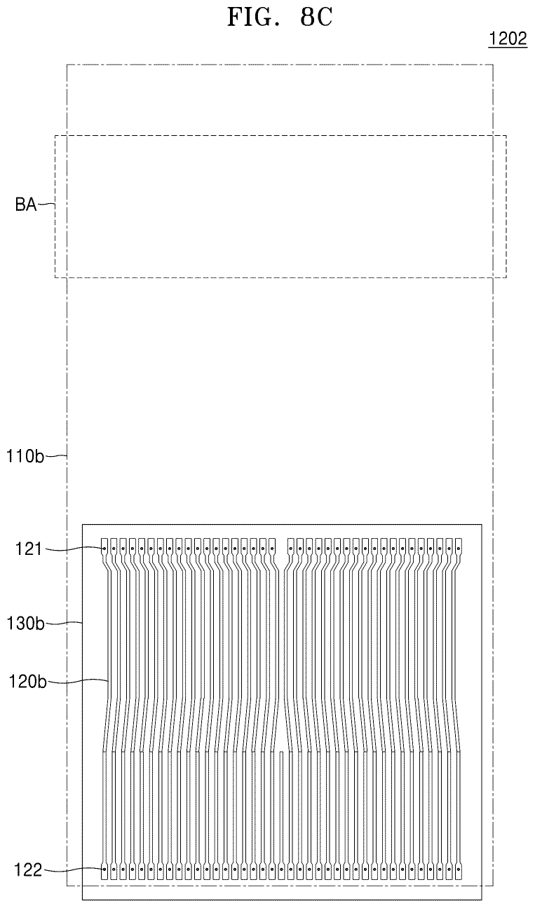

In FIGS. 8A, 8B, and 8C together, the display device 1202 may include the semiconductor chip 100, the driver printed circuit board 400, and the display panel 500 while the base film 110 is bent.

Most of the components constituting the display device 1202 and materials of the components described below are substantially the same as or similar to those described with reference to FIGS. 6A, 6B, and 6C above. Accordingly, for convenience of explanation, differences from the display device 1200 described above are mainly described.

The COF package 22 included in the display device 1202 may include an upper attachment 300 disposed to cover the semiconductor chip 100 and the molding material 140 on the first surface 110a of the base film 110.

The upper attachment 300 may perform substantially the same role as the attachment 200 described above and may include substantially the same material as the attachment 200. For example, the upper attachment 300 may include at least one of a stiffener or a heatsink.

In some implementations, the upper attachment 300 may be formed conformally according to the shape of each of the semiconductor chip 100 and the molding material 140. For example, the upper attachment 300 may have a flat upper surface and an inclined sidewall, but is not limited thereto.

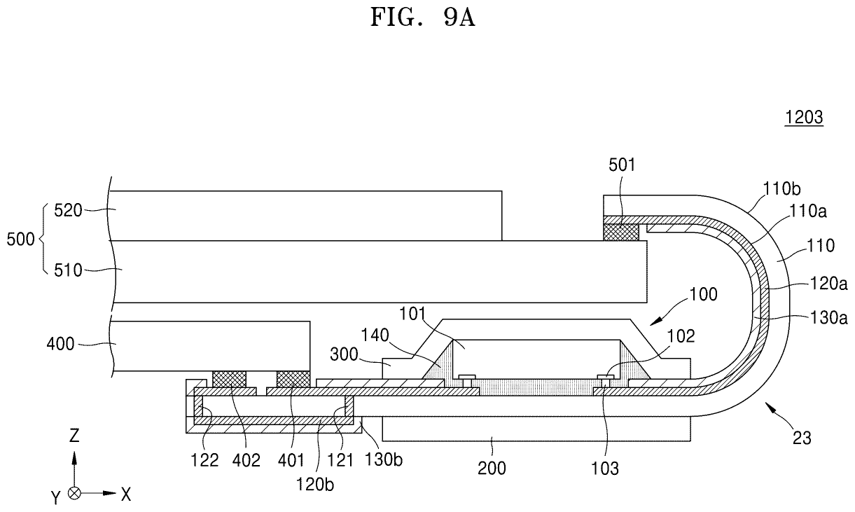

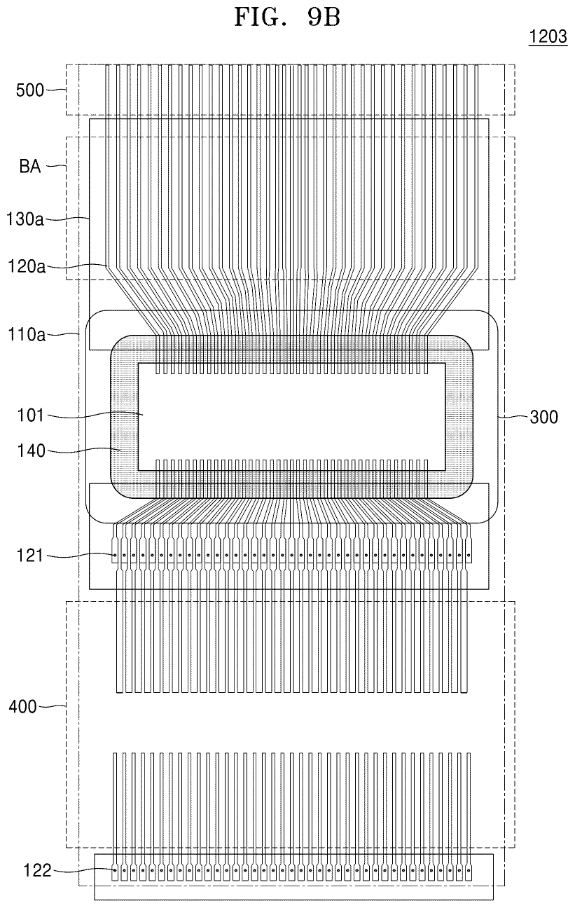

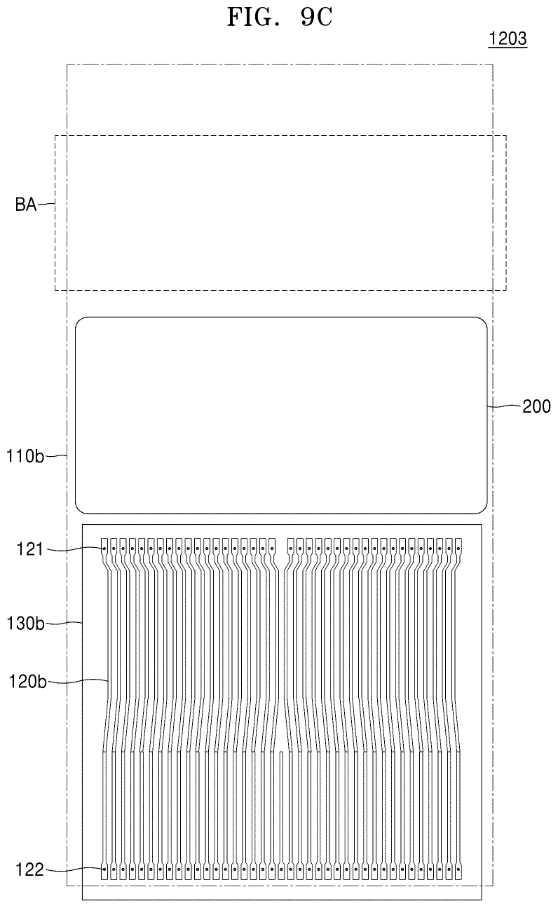

In FIGS. 9A, 9B, and 9C, the display device 1203 may include the semiconductor chip 100, the driver printed circuit board 400, and the display panel 500 while the base film 110 is bent.

Most of the components constituting the display device 1203 and materials of the components described below are substantially the same as or similar to those described with reference to FIGS. 6A, 6B, and 6C above. Accordingly, for convenience of explanation, differences from the display device 1200 described above are mainly described.

The COF package 23 included in the display device 1203 may include the attachment 200 disposed on an area in correspondence with the semiconductor chip 100 on the second surface 110b of the base film 110, and the upper attachment 300 disposed to cover the semiconductor chip 100 and the molding material 140 on the first surface 110a of the base film 110.

For example, the attachment 200 attached to the second surface 110b may be referred to as a lower attachment so as to contrast with the upper attachment 300. In some implementations, the attachment 200 may be referred to as a first attachment, and the upper attachment 300 may be referred to as a second attachment.

The lower attachment 200 and the upper attachment 300 may perform substantially the same role and may include substantially the same material. For example, the lower attachment 200 may include at least one of a stiffener or a heatsink, and the upper attachment 300 may include at least one of a stiffener or a heatsink.

In some implementations, the lower attachment 200 may be directly attached to the base film 110. For example, the second conductive line 120b and the second protective layer 130b are not formed in the chip lower area CA, so that the lower attachment 200 and the base film 110 may be bonded to directly contact with each other.

In addition, the upper attachment 300 may be formed conformally according to the shape of each of the semiconductor chip 100 and the molding material 140. For example, the upper attachment 300 may have a flat upper surface and an inclined sidewall, but is not limited thereto.

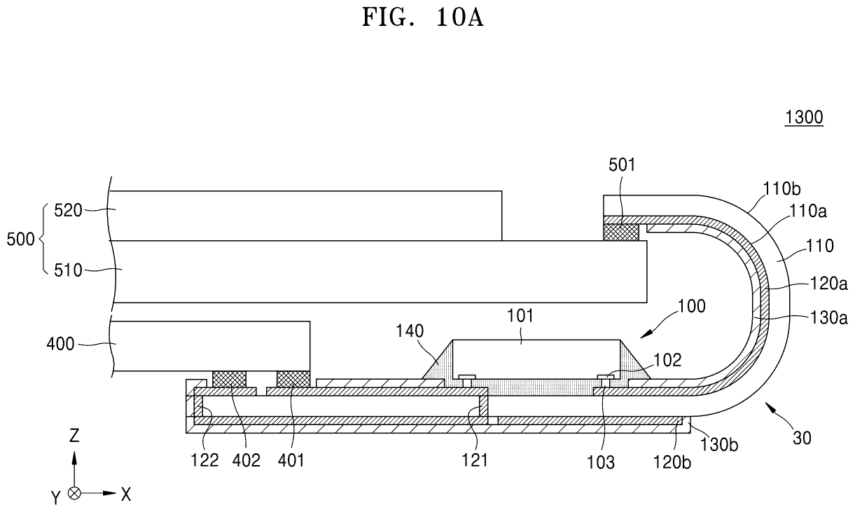

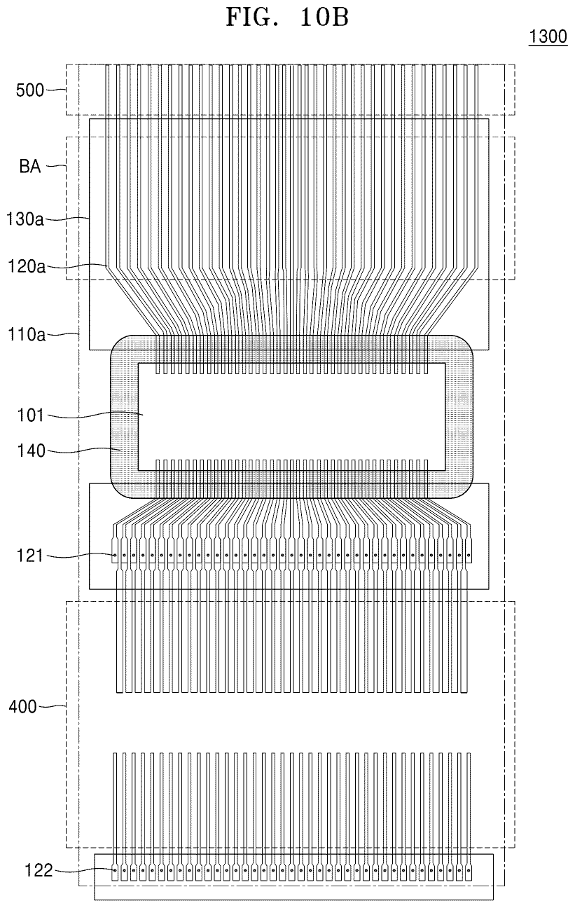

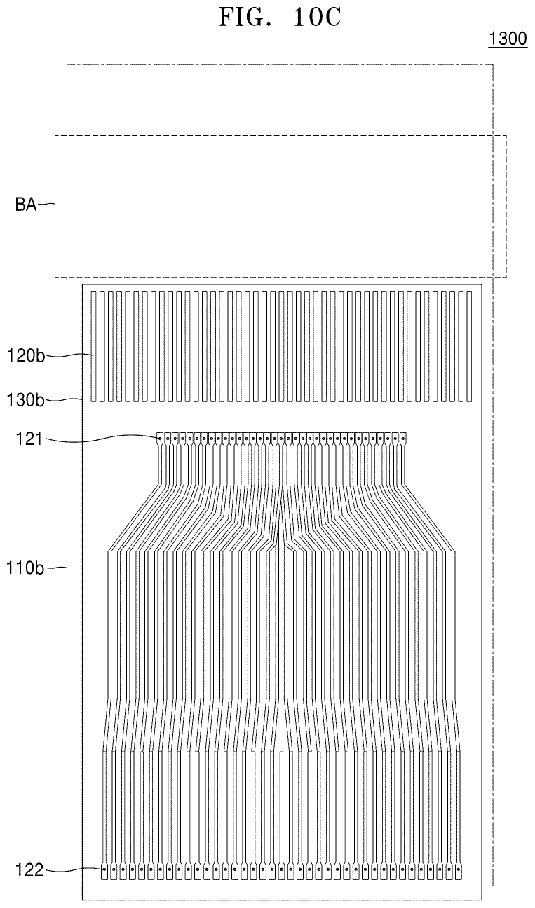

In FIGS. 10A, 10B, and 10C, the display device 1300 may include the semiconductor chip 100, the driver printed circuit board 400, and the display panel 500 while the base film 110 is bent.

Most of the components constituting the display device 1300 and materials of the components described below are substantially the same as or similar to those described with reference to FIGS. 4A, 4B, and 4C above. Accordingly, for convenience of explanation, differences from the display device 1100 described above are mainly described.

In the COF package 30 included in the display device 1300, the first via 121 may be located in an area below the semiconductor chip 100, and the second via 122 may be located an area below the driver printed circuit board 400.

As described above, the first and second vias 121 and 122 may be disposed in the base film 110 to electrically connect the first conductive line 120a to the second conductive line 120b. For example, the first and second vias 121 and 122 may penetrate (extend into) the base film 110 in the vertical direction (Z direction) and contact a lower surface of the first conductive line 120a and an upper surface of the second conductive line 120b.

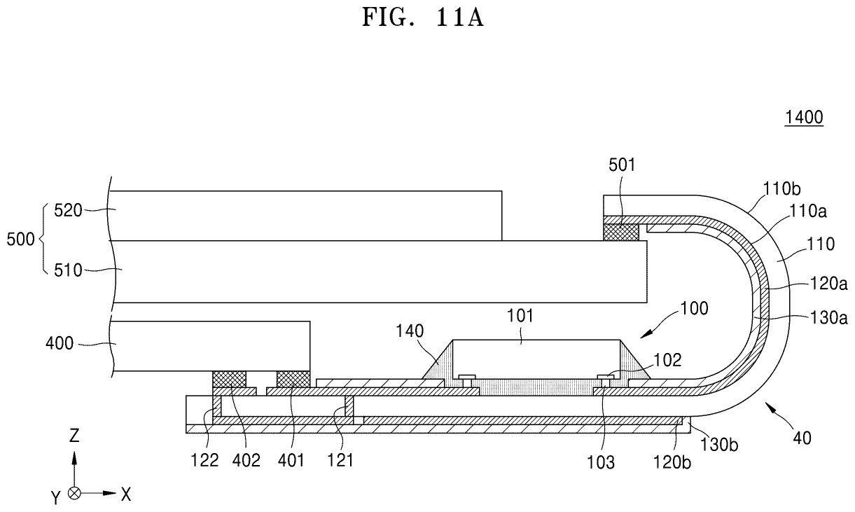

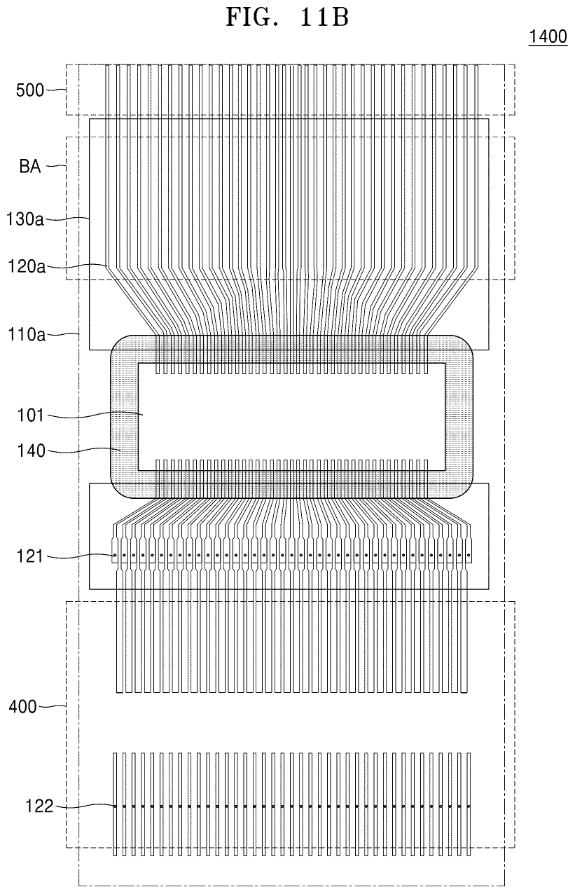

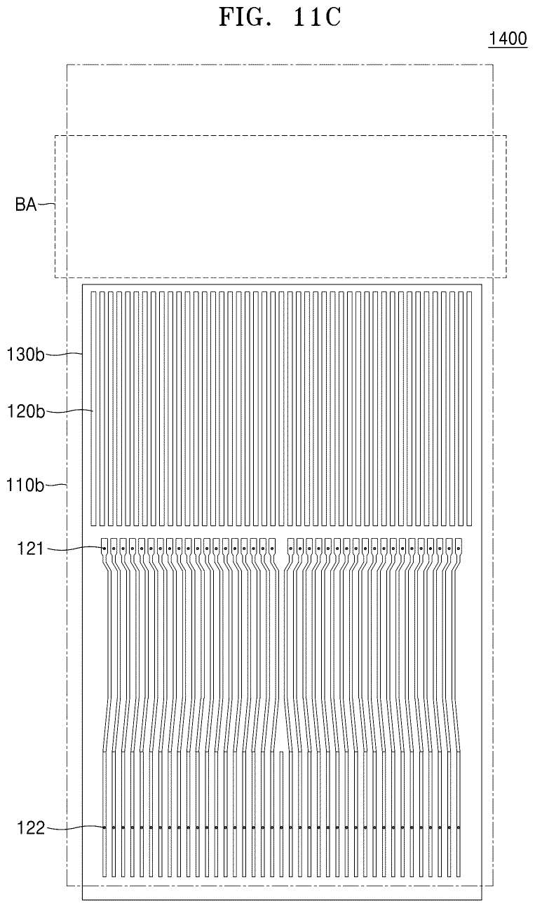

In FIGS. 11A, 11B, and 11C, the display device 1400 may include the semiconductor chip 100, the driver printed circuit board 400, and the display panel 500 while the base film 110 is bent.

Most of the components constituting the display device 1400 and materials of the components described below are substantially the same as or similar to those described with reference to FIGS. 4A, 4B, and 4C above. Accordingly, for convenience of explanation, differences from the display device 1100 described above are mainly described.

In the COF package 40 included in the display device 1400, the first protective layer 130a may not be formed on an area below the driver printed circuit board 400 in the first surface 110a of the base film 110. In addition, the second via 122 may be located in an area below the second bonding bump 402 of the driver printed circuit board 400.

As described above, the first protective layer 130a may be formed on the first surface 110a of the base film 110 to protect the first conductive line 120a from external physical and/or chemical damage. The first protective layer 130a may cover the first conductive line 120a while exposing the conductive pad 120P of the first conductive line 120a formed on the first surface 110a of the base film 110.

For example, the second via 122 is disposed in an area just below the conductive pad 120P connected to the second bonding bump 402 of the driver printed circuit board 400, so that the first protective layer 130a may not be formed in the area below the driver printed circuit board 400 in the first surface 110a of the base film 110.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A chip on film (COF) package comprising:
a base film having a first surface and a second surface, wherein the first surface and the second surface are opposite to each other;
at least one first conductive line extending in a first direction and disposed on the first surface of the base film;
at least one second conductive line extending in the first direction and disposed on the second surface of the base film;
a semiconductor chip disposed on the first surface of the base film and connected to the at least one first conductive line through a bump structure;
a protective layer covering a part of the first surface and a part of the second surface; and
a display panel disposed on the first surface and connected to the at least one first conductive line,
wherein the at least one second conductive line is excluded from the second surface between the semiconductor chip and the display panel.

2. The COF package of claim 1,
wherein an area on the second surface between the semiconductor chip and the display panel is a bending area, and
wherein the at least one second conductive line is excluded from the bending area.

3. The COF package of claim 2,
wherein the protective layer is disposed on the bending area of the first surface, and
wherein the protective layer is excluded from the bending area of the second surface.

4. The COF package of claim 2, wherein a length of the bending area in the first direction is about 1 mm to about 10 mm.

5. The COF package of claim 2, wherein an area on which the at least one second conductive line is disposed is a flat area.

6. The COF package of claim 1, further comprising at least one vertical via electrically connecting the at least one first conductive line to the at least one second conductive line,
wherein the at least one vertical via extends into the base film.

7. The COF package of claim 6, comprising a plurality of vertical vias, wherein each vertical via of the plurality of vertical vias is spaced apart from an adjacent vertical via of the plurality of vertical vias in the first direction from the semiconductor chip.

8. The COF package of claim 6, comprising a plurality of vertical vias,
wherein at least some vertical vias of the plurality of vertical vias are located in an area below the semiconductor chip, and
wherein remaining vertical vias of the plurality of vertical vias are spaced apart from one another in the first direction from the semiconductor chip.

9. The COF package of claim 1, further comprising:
at least one attachment disposed on at least one of the first surface or the second surface, in correspondence with the semiconductor chip,
wherein the at least one attachment is one of a stiffener and a heatsink.

10. The COF package of claim 1, wherein the base film is a flexible insulating substrate.

11. A chip on film (COF) package comprising:
a base film having an upper surface and a lower surface;
a plurality of first conductive lines extending in a first direction and disposed on the upper surface of the base film;
a first protective layer covering the plurality of first conductive lines;
a plurality of second conductive lines extending in the first direction and disposed on the lower surface of the base film;
a second protective layer covering the plurality of second conductive lines;
a semiconductor chip disposed at a center portion of the upper surface of the base film and electrically connected to the plurality of first conductive lines; and
a display panel disposed on one end of the upper surface of the base film and electrically connected to the plurality of first conductive lines,
wherein the plurality of second conductive lines and the second protective layer are excluded from an area of the lower surface of the base film from a center portion of the lower surface to one end of the lower surface.

12. The COF package of claim 11,
wherein the base film is bent so that the semiconductor chip and the display panel face each other, and
wherein the plurality of second conductive lines and the second protective layer are excluded in a bending area where the base film is bent.

13. The COF package of claim 12, wherein the plurality of first conductive lines and the first protective layer are disposed in the bending area.

14. The COF package of claim 13, wherein, in the bending area, a repulsive force of the upper surface of the base film and a repulsive force of the lower surface of the base film are different from each other.

15. The COF package of claim 14, wherein, in the bending area, the lower surface of the base film is exposed to the outside.

16. A display device comprising:
a chip on film (COF) package comprising a base film having a first surface and a second surface opposite to the first surface;
a display panel disposed to face one end of the first surface of the base film, the display paneling having a front surface comprising a plurality of pixels and a rear surface opposite to the front surface; and
a driver printed circuit board disposed facing another end of the first surface of the base film,
wherein the COF package comprises:
at least one first conductive line extending in a first direction and disposed on the first surface of the base film;
at least one second conductive line extending in the first direction and disposed on the second surface of the base film;
a semiconductor chip disposed on the first surface of the base film and connected to the at least one first conductive line through a bump structure; and
a protective layer covering a part of the first surface and a part of the second surface,
in the COF package, the at least one second conductive line is excluded in a bending area where the base film is bent toward a rear surface of the display panel.

17. The display device of claim 16, further comprising a plurality of pads disposed on the first surface,
wherein the plurality of pads electrically connect the at least one first conductive line and the driver printed circuit board to each other.

18. The display device of claim 16,
wherein the protective layer is disposed on the bending area of the first surface, and
wherein the protective layer is excluded from the bending area of the second surface.

19. The display device of claim 16, further comprising at least one attachment disposed on at least one of the first surface or the second surface corresponding to the semiconductor chip,
wherein the at least one attachment is one of a stiffener and a heatsink.

20. The display device of claim 16, wherein the semiconductor chip and the driver printed circuit board are disposed to face the rear surface of the display panel.
